(19) United States
(12) Patent Application Publication
(10) Pub. No.: US 2024/0204128 A1
(43) Pub. Date: Jun. 20, 2024

(54) HIGH VOLTAGE AND HIGH-POWER DIAMOND BASED JUNCTION-GATE FIELD EFFECT TRANSISTOR (JFET) SWITCH WITH PHOTO-CONTROLLED GATE

(71) Applicant: Lawrence Livermore National Security, LLC, Livermore, CA (US)

(72) Inventors: Qinghui Shao, Fremont, CA (US); Lars F. Voss, Livermore, CA (US); Soroush Ghandiparsi, Pleasant Hill, CA (US)

(21) Appl. No.: 18/428,200

(22) Filed: Jan. 31, 2024

Related U.S. Application Data
(63) Continuation-in-part of application No. 18/480,996, filed on Oct. 4, 2023.
(60) Provisional application No. 63/378,393, filed on Oct. 5, 2022.

(51) Int. Cl. H01L 31/112; H01L 31/0216; H01L 31/028

(52) U.S. Cl. CPC H01L 31/1126; H01L 31/02161; H01L 31/02164; H01L 31/028

(57) ABSTRACT

Devices, methods and techniques related to high voltage and high-power diamond transistors are disclosed. In one example aspect, a switch operable under high-voltage and high-power includes a P-type diamond layer doped with an acceptor material and an N-type diamond region doped with a donor material. The P-type diamond layer is at least partially embedded the N-type diamond region. The switch includes a layer comprising one or more apertures configured to allow illumination from a light source to pass through to reach the N-type diamond region, a source contact and a drain contact that are at least partially in contact with the P-type diamond layer; and a gate in contact with at least an area of the N-type diamond region.

### CROSS-REFERENCE TO RELATED APPLICATION(S)

This patent document is a continuation-in-part of U.S. application Ser. No. 18/480,996, filed Oct. 4, 2023, which claims the benefit of priority to U.S. Provisional Patent Application No. 63/378,393, filed on Oct. 5, 2022. The contents of the above-noted applications are incorporated herein by reference in its entirety.

### FEDERALLY SPONSORED RESEARCH OR DEVELOPMENT

This invention was made with Government support under Contract No. DE-AC52-07NA27344 awarded by the United States Department of Energy. The Government has certain rights in the invention.

### TECHNICAL FIELD

This document generally relates to transistors, and particularly to high voltage and high-power diamond transistors.

### BACKGROUND

The power electronics systems ranging from kilowatts to gigawatts of power with high efficiency are in need for energy conversion.

### BRIEF DESCRIPTION OF THE DRAWINGS

FIG. 1 is a schematic diagram of an example diamond Junction-gate Field Effect Transistor (JFET) switch in accordance with one or more embodiments of the present technology.

FIG. 2 is another schematic illustration of an example diamond JFET switch in accordance with one or more embodiments of the present technology.

FIG. 3 illustrates an example plot of drain current varying with different substrate voltages in accordance with one or more embodiments of the present technology.

FIG. 4 illustrates an example drain current and substrate current with respect to different substrate voltages in accordance with one or more embodiments of the present technology.

FIG. 5A illustrates a temporal change of light intensity and substrate voltage in accordance with one or more embodiments of the present technology.

FIG. 5B illustrates a temporal change of a drain current corresponding to the light intensity and substrate voltage in FIG. 5A.

FIG. 6A illustrates an example hole concentration profile at T=10 ms corresponding to FIGS. 5A-B in accordance with one or more embodiments of the present technology.

FIG. 6B illustrates an example hole concentration profile at T=20 ms corresponding to FIGS. 5A-B in accordance with one or more embodiments of the present technology.

FIG. 6C illustrates an example hole concentration profile at T=30 ms corresponding to FIGS. 5A-B in accordance with one or more embodiments of the present technology.

FIG. 6D illustrates an example hole concentration profile at T=40 ms corresponding to FIGS. 5A-B in accordance with one or more embodiments of the present technology.

FIG. 6E illustrates an example hole concentration profile at T=50 ms corresponding to FIGS. 5A-B in accordance with one or more embodiments of the present technology.

FIG. 6F illustrates an example hole concentration profile at T=70 ms corresponding to FIGS. 5A-B in accordance with one or more embodiments of the present technology.

FIG. 7 is a flowchart representation of an example procedure to operate a switch device in accordance with one or more embodiments of the present technology.

FIG. 8 illustrates simulation results of 5 um and 10 um channel diamond JFET together with GaN and diamond limits in the plot of Baliga's Figures of Merit (FOM).

FIG. 9 illustrates an example diamond JFET with multiple apertures as junction termination extensions in accordance with one or more embodiments of the present technology.

FIG. 10 illustrates another example diamond JFET with multiple apertures as junction termination extensions in accordance with one or more embodiments of the present technology.

FIG. 11 illustrates yet another example diamond JFET with multiple apertures as junction termination extensions in accordance with one or more embodiments of the present technology.

FIG. 12A illustrates an example planar JFET switch corresponding to the configuration shown in FIG. 2 in accordance with one or more embodiments of the present technology.

FIG. 12B illustrates an example distribution of free electrons and a hole channel of a planar configuration in accordance with one or more embodiments of the present technology.

FIG. 13A illustrates an example partially embedded P-layer JFET switch in accordance with one or more embodiments of the present technology.

FIG. 13B illustrates an example three-dimensional schematic diagram of multiple Fin-FET devices in parallel in accordance with one or more embodiments of the present technology.

FIG. 13C illustrates an example distribution of free electrons and a hole concentration profile of a Fin-FET configuration at time of 300 ns after the gate light is turned on in accordance with one or more embodiments of the present technology.

FIG. 14A illustrates an example fully embedded P-layer JFET switch in accordance with one or more embodiments of the present technology.

FIG. 14B illustrates an example three-dimensional schematic diagram of multiple Optical-Gate-All-Around (OGAA) FET devices connected in parallel in accordance with one or more embodiments of the present technology.

FIG. 14C illustrates an example distribution of free electrons and a hole concentration profile of an OGAA-FET configuration at time of 300 ns after the gate light is turned on in accordance with one or more embodiments of the present technology.

FIG. 15 illustrates example plots showing transient drain currents normalized to their maximum values in linear scale and logarithm scale in accordance with one or more embodiments of the present technology.

FIG. 16 illustrates yet another example diamond JFET in accordance with one or more embodiments of the present technology.

FIG. 17 illustrates two example implementations of a gradient mask (Mask2) in accordance with one or more embodiments of the present technology.

FIG. 18 illustrates an example comparison of electric field profiles with and without JTE light in a DOG-FET under the steady state in accordance with one or more embodiments of the present technology.

FIG. 19 illustrates example simulated electric fields at the interface of P channel and substrate in accordance with one or more embodiments of the present technology.

FIG. 20 illustrates an example three-dimensional schematic diagram of an optical JTE in OGAA Diamond Optically Gated (DOG) FET in accordance with one or more embodiments of the present technology.

### DETAILED DESCRIPTION

Due to diamond's high thermal conductivity (22 W/cmK), high hole mobility (>2000 cm2/Vs), and high critical electric field (>10 MV/cm), diamond has overwhelming advantages over silicon and other wide bandgap materials (e.g., 4H-SiC, GaN, GaO and AlN) for ultra-high-voltage and high-temperature applications. Recent developments have demonstrated the availability of relative low cost and low dislocation density (e.g., 10⁵ cm⁻²) of high pressure high temperature (HPHT) substrates. High quality of P-type diamond layer by chemical vapor deposition is also available. However, the material has not yet delivered the expected high performance, mainly due to the absence of shallow donor and acceptor impurities. For example, one of the well investigated donors is nitrogen that has an activation energy of 1.7 eV. The acceptor can be boron having an activation energy of 0.38 eV. At room temperature, the deep donors offer no free electrons even at high doping levels (e.g., 10¹⁸ to 10¹⁹ cm⁻³): only 6×10¹⁴ cm⁻³ free hole concentration is available with 2×10¹⁷ cm⁻³ net doped boron. High-temperature (HT) operation using the material may alleviate the issue of the incomplete ionization of dopant species but can also result in severe thermal management issues and affect the overall stability and long-term reliability.

This patent document, among other features, discloses techniques that can be implemented in various embodiments to optically activate the deep donors (also referred to as impurities) to enable a viable route for diamond transistors in high voltage switch applications. The disclosed techniques can be particularly suitable for JFETs. It is noted that the discussions below focus on using nitrogen as the deep donor and boron as the acceptor. The disclosed techniques, however, are also applicable to other donor/acceptor materials suitable for diamond layers. For example, donors in diamond can be Nitrogen, Phosphorus, Oxygen and their complexes. The acceptors can be boron, and its complexes. FETs implemented using the disclosed techniques can also referred to as Diamond Optically Gated (DOG) FETs.

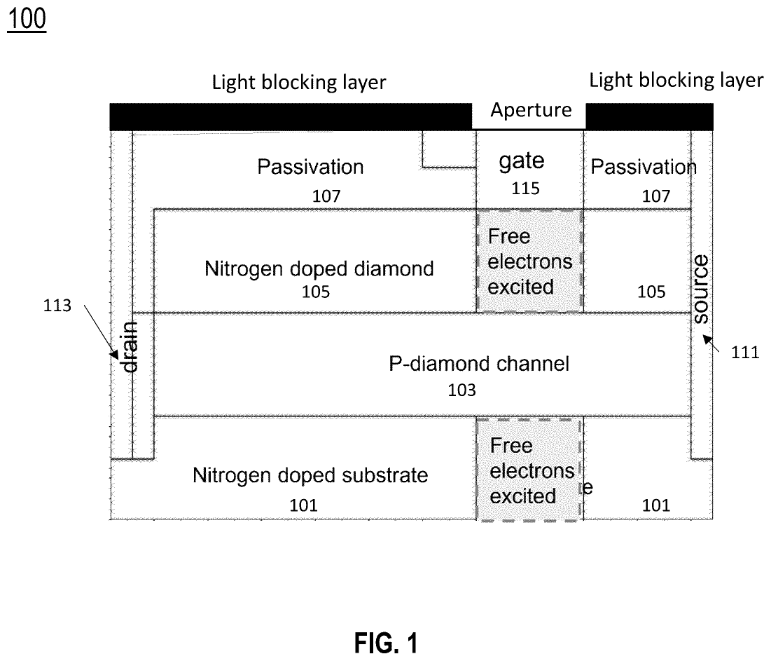

FIG. 1 is a schematic illustration of an example diamond JFET switch 100 in accordance with one or more embodiments of the present technology. As illustrates in FIG. 1, a nitrogen doped N-type diamond substrate 101 is provided. The doping level can be in the 10¹⁹ cm⁻³ range with 1.7 eV ionization energy. A P-type boron-doped diamond layer 103 can be epitaxially grown on top of the nitrogen doped N-type substrate. In some embodiments, the P-type boron-doped diamond layer 103 can have a thickness of around of 0.5 um (e.g., between 0.1 um to 1 um) with an ionization energy of around 0.38 eV. Another nitrogen doped N-type diamond layer 105 can be epitaxially grown on top of the boron-doped P-type diamond layer 103. The thickness of the nitrogen doped diamond layer 105 can also be around 0.5 um.

In some embodiments, in addition to the nitrogen and boron doped layers, a dielectric passivation layer 107 can be deposited on top of the nitrogen doped N-type diamond layer 105. The source 111 and drain 113 contacts can be formed by etching through the passivation layer 107, the nitrogen doped diamond N-type layers (101, 105), and the boron-doped diamond P-type layer 103, followed by metal deposition. The gate contact 115 can be formed by etching through the passivation layer 107 and by deposition of transparent conductive gate such as indium-tin-oxide (ITO) film to contact the nitrogen doped diamond N-type layer 105 A light blocking layer is deposited on top of the passivation layer. The light blocking layer can comprise any materials that reflects or blocks light (e.g., aluminum). An aperture (e.g., having a width of around 2 um) is provided from the top (e.g., by etching at least part of the light blocking layer). When light from a light source provides illumination through the aperture, the light goes through the passivation and P-type layer 103 without absorption, because there is no deep donor presence. However, the light that reaches the N-type layer 105 and N-type substrate 101 gets absorbed. The free electrons can be photo-excited from deep donors to conduction band. The photon energy of the light needs to be higher than the activation energy of the doping material (e.g., nitrogen at 1.7 eV) and the wavelength of the light needs to be appropriate for absorption based on the doping material. In this specific example, the threshold wavelength is around 730 nm. The wavelength is preferably shorter than the threshold wavelength as light having a longer wavelength may not be effectively absorbed. The conduction P-channel can then be modulated by changing the gate voltage.

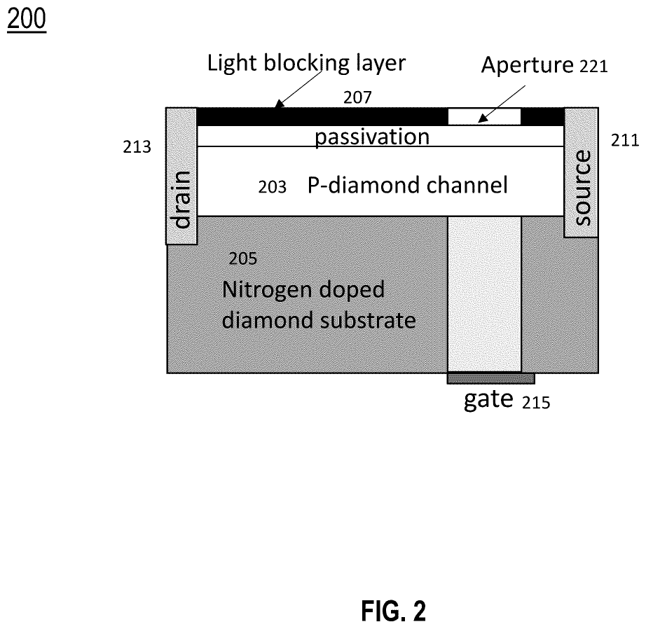

In some embodiments, to case the difficulty of epitaxial growth of N-diamond layers on top of P-diamond layer, an example diamond JFET switch 200 is schematically illustrated in FIG. 2. In this example, the nitrogen doped substrate 205 having a thickness of 100-500 μm is in use. The boron-doped P-type layer 203 is deposited on top of the N-type substrate 205. The thickness of the P-type layer 203 can be 0.1 μm to 1 μm, or even at the mm level. In some embodiments, a passivation layer can be deposited on top of the P-type layer 203. Drain contact 213 and source contact 211 are deposited in contact with P-type diamond layer after etching through of passivation and P-diamond layer. Gate contact 215 is formed by metal deposition on the backside of the substrate 205. A light blocking layer 207 is deposited on the passivation layer. The light blocking layer 207 can comprise any materials that reflects or blocks light (e.g., aluminum). An aperture 221 (e.g., having a width of around 2 μm) is provided from the top (e.g., by etching at least part of the light blocking layer 207). When light from a light source provides illumination through the aperture, the light goes through the passivation layer and P-type layer 203 without absorption. The light reaches the N-type substrate 205 and the free electrons can be photo-excited in the illuminated region. The gate voltage on the back is transferred to P-type channel and modulates the current conduction.

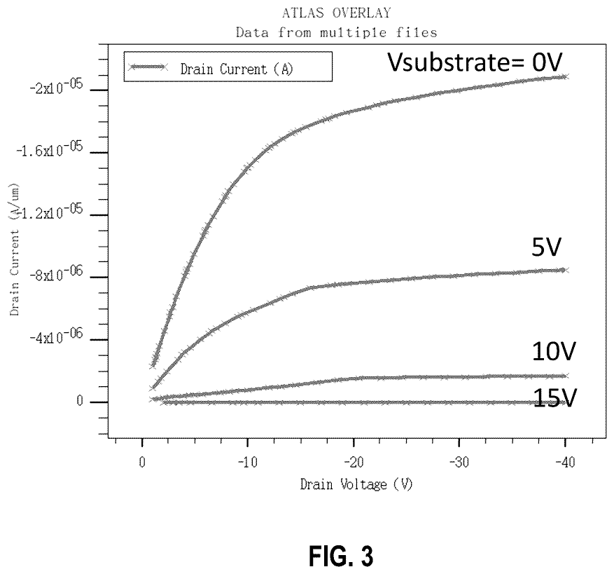

FIG. 3 illustrates example plots of drain current versus drain voltage for different substrate voltages (also referred to as gate voltages) in accordance with one or more embodiments of the present technology. In this example, the light from the light source has a wavelength of 550 nm and a power of 11 W/cm². When the substrate/gate voltage is set to 0V, there is a steady build-up of the conduction current between the source and the drain. When the substrate/gate voltage is increased, the current between the source and the drain is gradually decreased. At 15V, for example, the current between the source and the drain is totally blocked. The desired conduction current (ON state) can be tuned by varying the substrate/gate voltage. Once it is reached, the light can be turned off and the substrate/gate voltage can be turned off. The switch can memorize the current channel condition and the electric current remains conducting. The portion of the N-layer(s) without light activation remains semi-insulating.

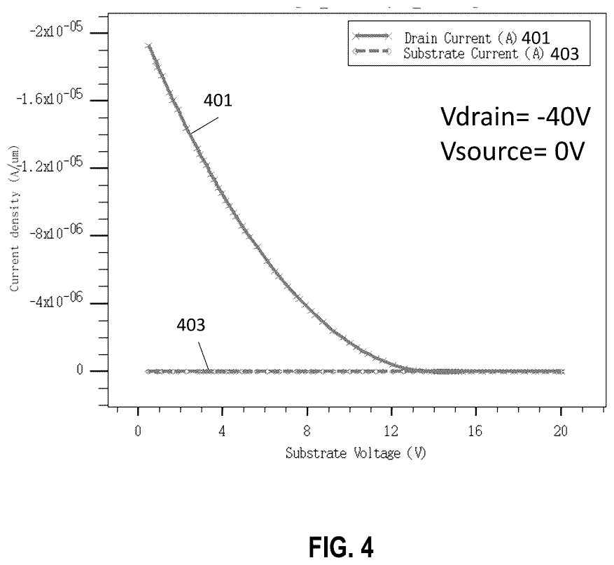

The current can be depleted again by tuning up the substrate/gate voltage. FIG. 4 illustrates example plots of drain current and substrate/gate current versus substrate/gate voltage with a certain drain-source voltage of −40V in accordance with one or more embodiments of the present technology. As shown in FIG. 4, the drain current 401 reduces as the substrate (gate) voltage increases, and the substrate (gate) current 403 remains at a very low level (e.g., close to 1×10⁻¹¹ A/μm). The layer(s) can be fully depleted at around 13V substrate (gate) voltage.

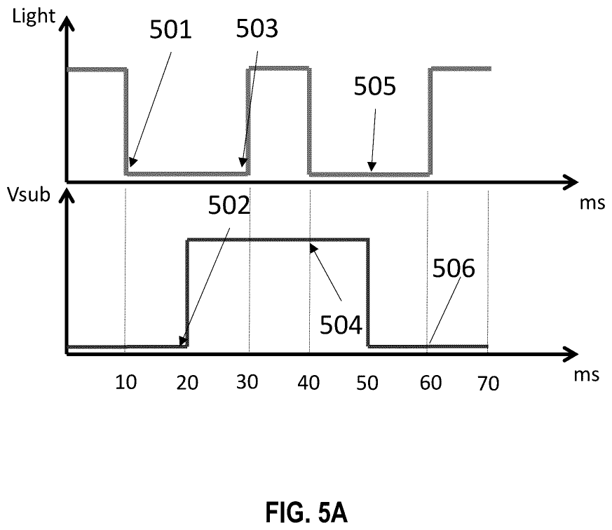

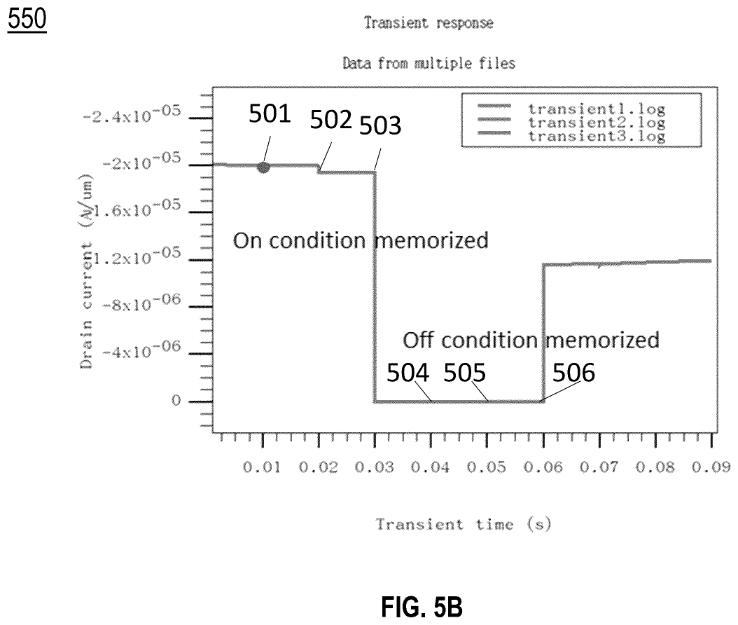

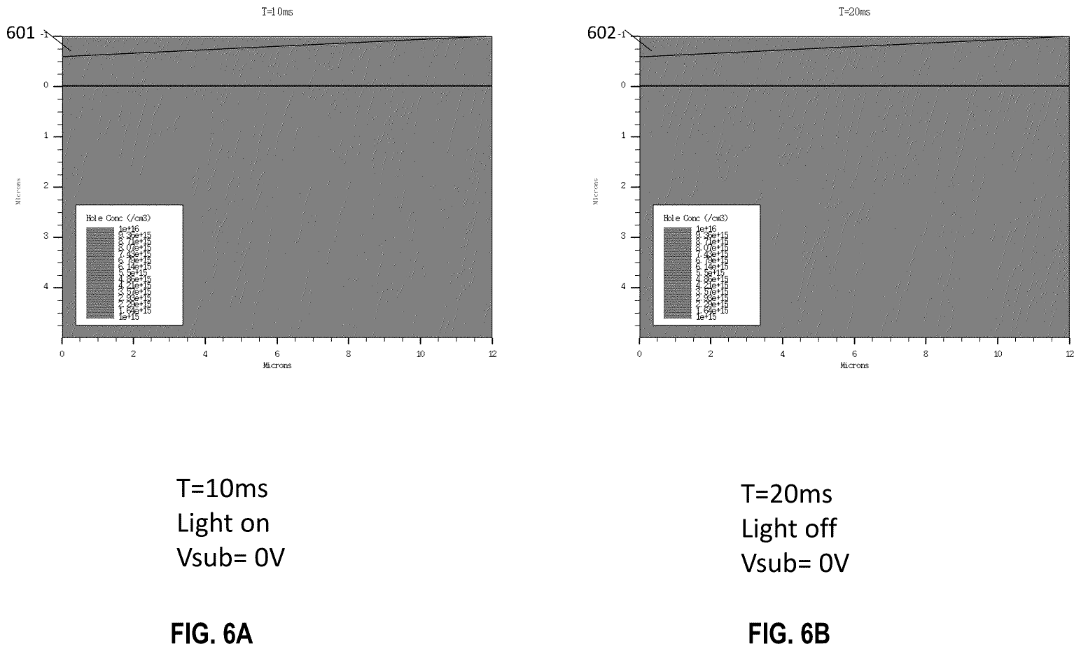

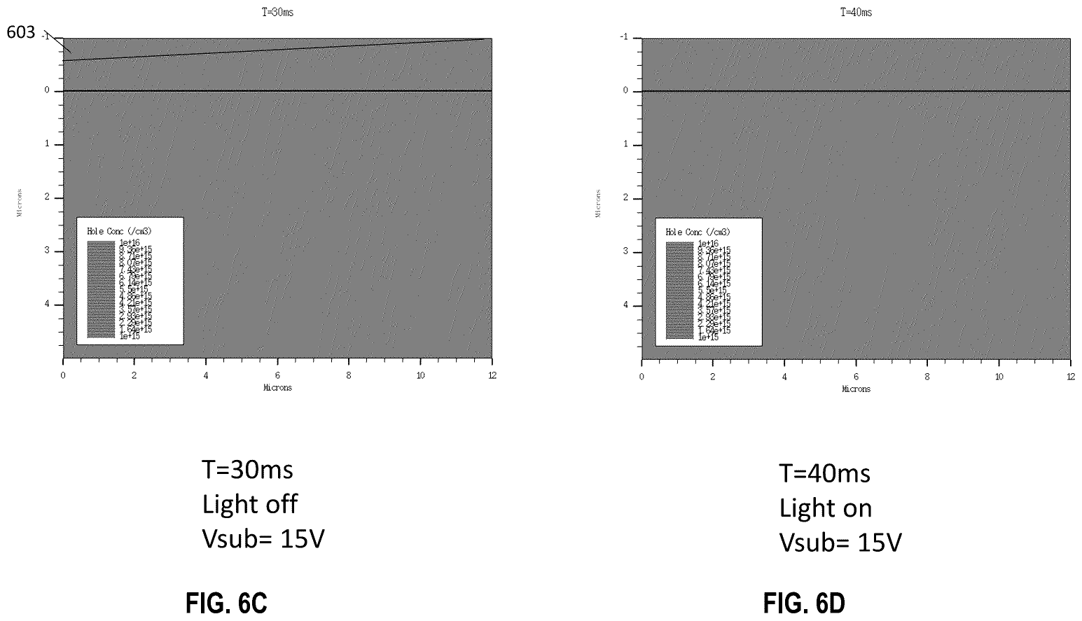

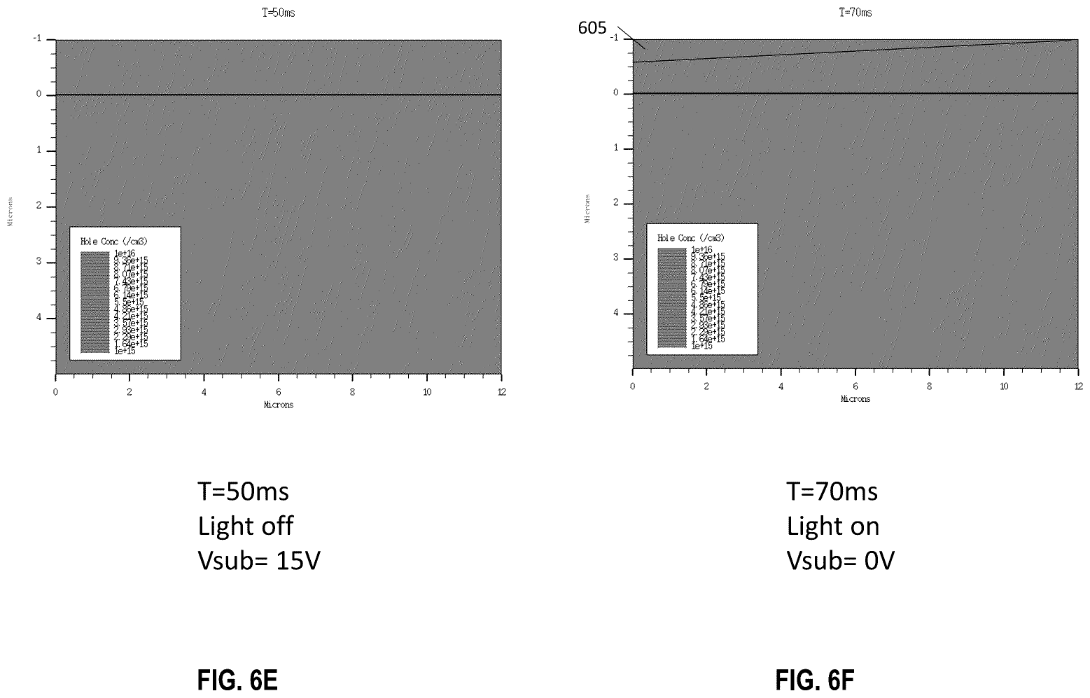

Turning on or off a switch device implemented using the disclosed techniques does not require the continuous application of the light or the substrate/gate voltage. Once in a particular state (e.g., on or off), the conduction channel between the source and the drain of the switch device can be “locked” such that the switch device can memorize its state for a prolonged period of time. The prolonged period of time is determined based on the material properties (e.g., RC delay and/or resistance) and can last minutes, hours, or even days. The temporal change of light intensity, substrate (gate) voltage, and the conduction current between the source and the drain are further illustrated in FIGS. 5A-5B and 6A-6F. The time instances, T=10 ms, 20 ms, 30 ms, 40 ms, 50 ms, and 60 ms, when different actions take place, are labeled as 501, 502, 503, 504, 505, and 506 in FIGS. 5A-6F.

As shown in 5A and 6A, prior to T=10 ms (501), the switch device can be turned on by switching the light source on and setting the substrate/gate voltage Vsub to 0V. A conduction current can be produced between the source and the drain (as shown in FIG. 5B and FIG. 6A). The conduction current in FIG. 6A is illustrated by the expanded area of high hole concentration labeled as 601. Similar labeling convention is used in FIGS. 6B-6F. At T=20 ms (502), as shown in FIG. 5A, the light source can be switched off without impacting the on-state of the switch device. The substrate (gate) voltage can remain to be 0V. The device can memorize the ON condition and there remains a conduction current 602 between the source and the drain (as shown in FIG. 5B and FIG. 6B). At this point, a change of substrate/gate voltage may not change its conduction current. For example, at T=30 ms (503), the substrate/gate voltage has ramped up to 15V and held for 10 ms, there is no conduction current change as shown in FIG. 5B

The switch device can be changed to be in the OFF state by switching the light source on and setting the substrate/gate voltage Vsub to 15V. For example, at T=30 ms (503), the device is still in the ON state, having a conduction current 603 between the source and the drain with a substrate/gate voltage of 15V (as shown in FIG. 5B and FIG. 6C). After switching the light source on, the switch device turns into the OFF state at T=40 ms (504) (as shown in FIG. 5B and FIG. 6D). By keeping the light off, the device can also memorize the OFF state (as shown in FIG. 5B). When the substrate/gate voltage Vsub is changed to 0V at T=50 ms, the conduction current remains to be low (as shown in FIG. 5B and FIG. 6E) and the device remains off. The device can be turned back on again by switching the light after T=60 ms (506) with substrate voltage Vsub being 0V. As shown in FIG. 6F, a conduction current 605 is again established at T=70 ms.

Due to the “locking” or memorization properties of the switch device, the light that is applied can be a pulse to reduce cost and energy consumption. For example, a light pulse having a short cycle time between 1 to 10 us (e.g., 4 us at 250 KHz frequency) can be used to promptly turn on (activate) and off (reactive) the switch device. The cycle time and/or frequency of the pulse light can be determined by the carrier lifetime of the doping material(s) and/or the N-type substrate thickness. The substrate/gate voltage can also be pulsed. The shortest cycle time and/or maximum frequency of the pulsed voltage can be in the same range of light pulse.

As mentioned above, the deep donor with 2×10¹⁷ cm⁻³ net doped boron can offer only 6×10¹⁴ cm⁻³ free hole concentration at room temperature. In some applications, it may be desirable to increase the hole concentration to reduce the on resistance. To achieve this, a second light source can be switched on to excite free holes. The desired wavelength of the second light source can be longer than the first light source such that the photon energy of the second light is greater than the activation energy of boron but smaller than the activation energy of nitrogen. The channel conductivity is linearly proportional to the light intensity, and a shorter wavelength is preferred to achieve higher absorption coefficient. In some embodiments, the free hole concentration can be increased by two orders of magnitude depending on the acceptor optical cross section and the intensity of the second light. Unlike the first light source, however, the second light source needs to remain on to maintain the elevated conduction current. Therefore, usage of the second light source can be suitable for short duty-cycle applications.

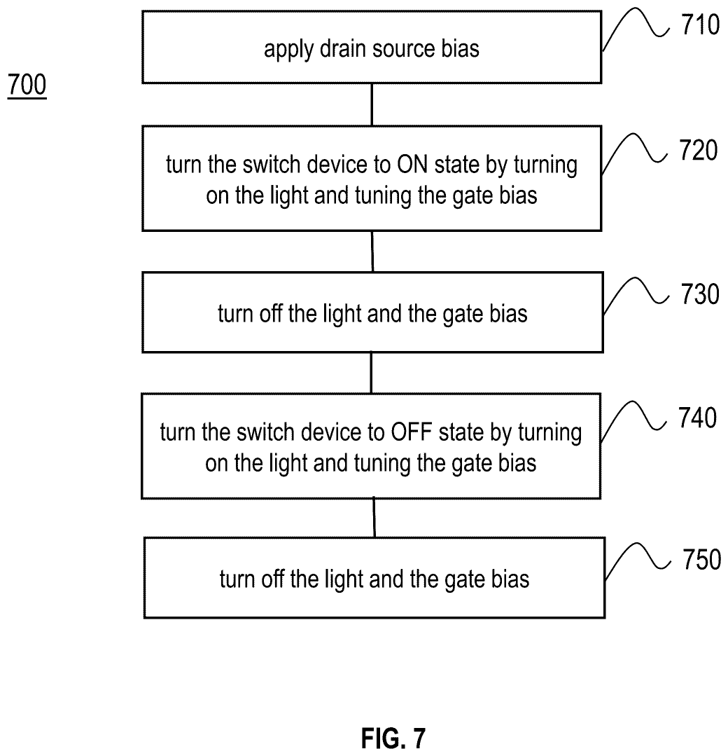

FIG. 7 is a flowchart representation of an example procedure 700 to operate a switch device in accordance with one or more embodiments of the present technology. The procedure 700 includes the following operations:

Operation 710: Apply an appropriate drain-to-source bias voltage.

Operation 720: Turn on the first light source (also referred to as the gate-control-light) and tune the gate bias (e.g., 0V) to meet desired conduction current so that the switch device is in the ON state.

Operation 730: Turn off the gate-control light and adjust the gate bias down to 0V once the conduction current is maintained. The switch device maintains its ON state.

Operation 740: To turn the switch device into the OFF state, turn on the gate-control light and adjust the gate bias to deplete the channel.

Operation 750: Turn off the gate-control light and adjust the gate bias down to 0V. The channel remains blocked, and the switch device maintains its OFF state.

Operation 720 can be repeated to bring the switch device back to ON state.

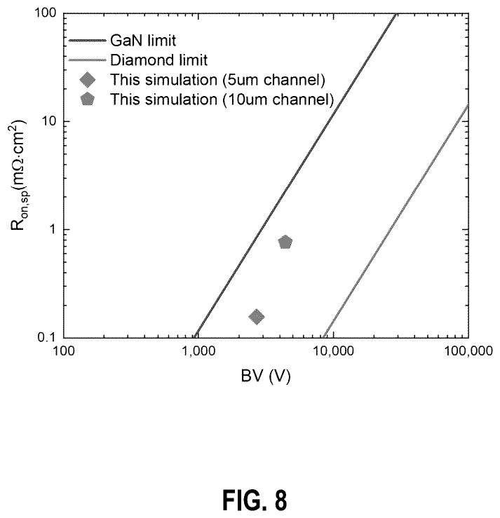

FIG. 8 illustrates simulation results of 5 μm and 10 μm channel diamond JFET together with GaN and diamond limits in the plot of Baliga's Figures of Merit (FOM). The simulated specific on resistance (Ron, sp) and breakdown voltage are 0.157 mΩ-cm², 2700 V for 5 um channel devices and 0.762 mΩ-cm², 4400 V for 10 um channel devices, respectively. As shown in FIG. 8, the results place the disclosed devices beyond the GaN limit in the plot of Baliga's figure of merit.

In some embodiments, to mitigate a high electric field occurring at the corner of gate and p-type diamond layer interface, the disclosed techniques can be applied to Junction termination extension (JTE) technique. JTE is a technique for increasing avalanche breakdown voltage and controlling surface electric fields in PN junctions. The technology of JTE is widely used in power diodes and transistors to improve the breakdown voltage. Due to the unique lattice structure and extreme material strength, doping depths are limited to 10 nm by means of a high energy ion implantation process in diamond. Combined with low ionization rates of deep dopants, JTEs can be less effective in diamond. The disclosed optical stimulated excitation offers a feasible way to enable the function of JTEs without complicated ion implantation and activation processes. The periodic junction locations and spacings are optically defined by apertures etched in a light blocking layer. The effective electron concentration and conductivity are modulated by incident light intensity.

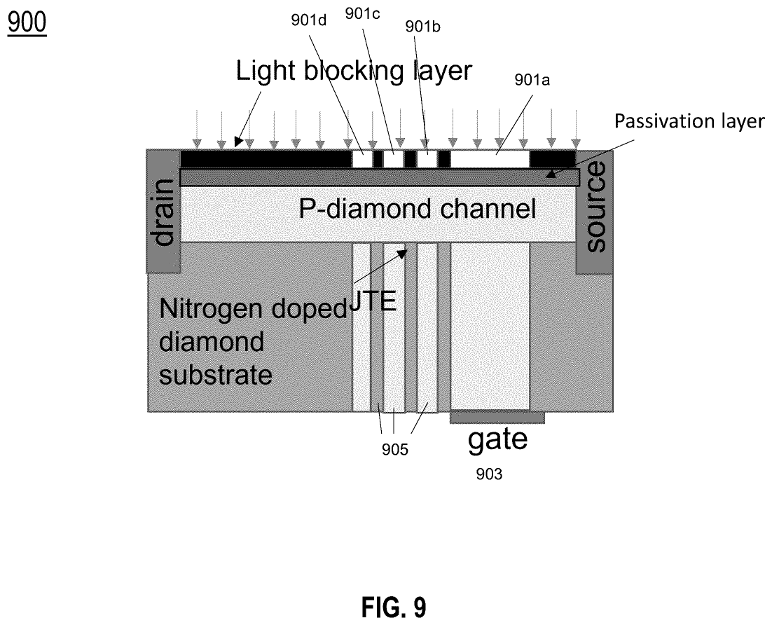

FIGS. 9-11 illustrate three device designs with nitrogen doped diamond substrates as gates. FIG. 9 illustrates an example diamond JFET 900 with multiple apertures as junction termination extensions in accordance with one or more embodiments of the present technology. The light shining through the apertures 901a, 901b, 901c, 901d generates free electrons (shown as light gray regions in FIG. 9). The periodically spaced conductive and resistive features mitigate the local high electric field away from the gate corner. The back gate metal 903 is aligned to the desired gate region avoiding contact with JTEs 905 such that the JTEs do not short to the gate.

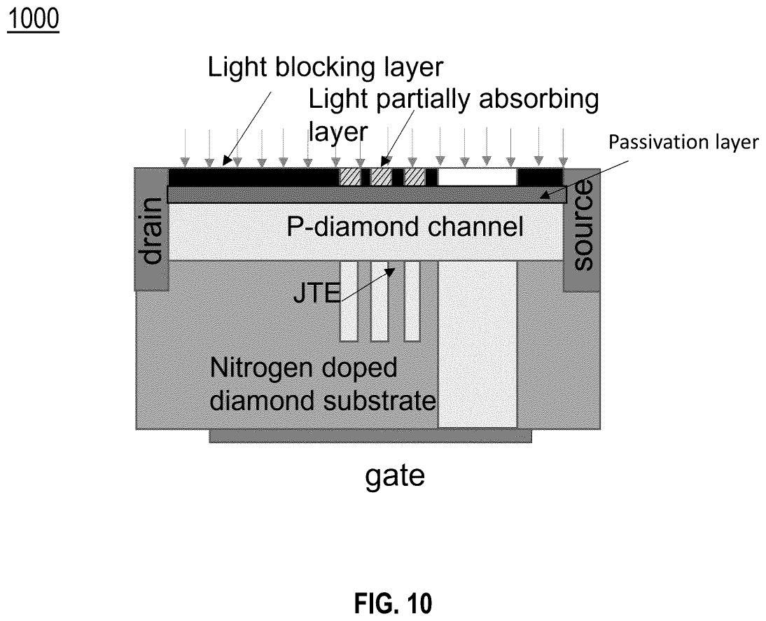

FIG. 10 illustrates another example diamond JFET 1000 with multiple apertures as junction termination extensions in accordance with one or more embodiments of the present technology. In this example, a partially light-absorbing material is filled in the apertures to allow easier alignment of the gate at the bottom. The light that goes through the apertures is partially absorbed, so the generated electron concentration at the back of the substrate is not sufficient to short the gate on the backside (as illustrated by light gray channels that do not reach the bottom of the substrate). The generated electron concentration, however, is high enough at the interface of p-diamond channel to enable the JTEs function in reducing the local high electric fields. In this design, no fine alignment between top to bottom surfaces is required, and a blanket back-gate metal that covers a large section of the backside can be implemented.

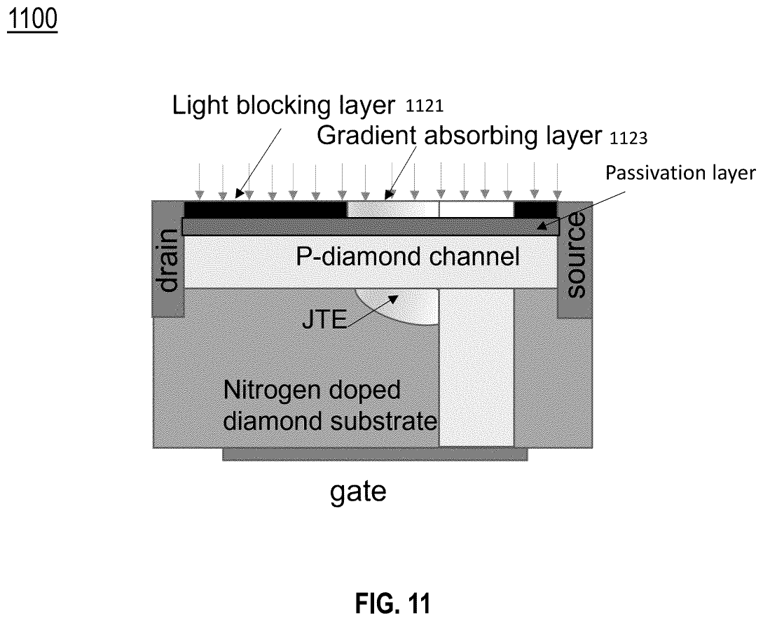

FIG. 11 illustrates yet another example diamond JFET 1100 with multiple apertures as junction termination extensions in accordance with one or more embodiments of the present technology. In this example design, a single aperture is filled with gradually light absorbing (e.g., a gradient index or a gradient thickness) material to gradually absorb the light. A gradient of light intensity is formed at the interface when it propagates through the channel layer. It induces a gradually reduced electron concentration away from the gate position. The layer with gradually changed resistance reduces the local high field and improve the device breakdown voltage. This design does not require fine alignment between top to bottom surfaces either.

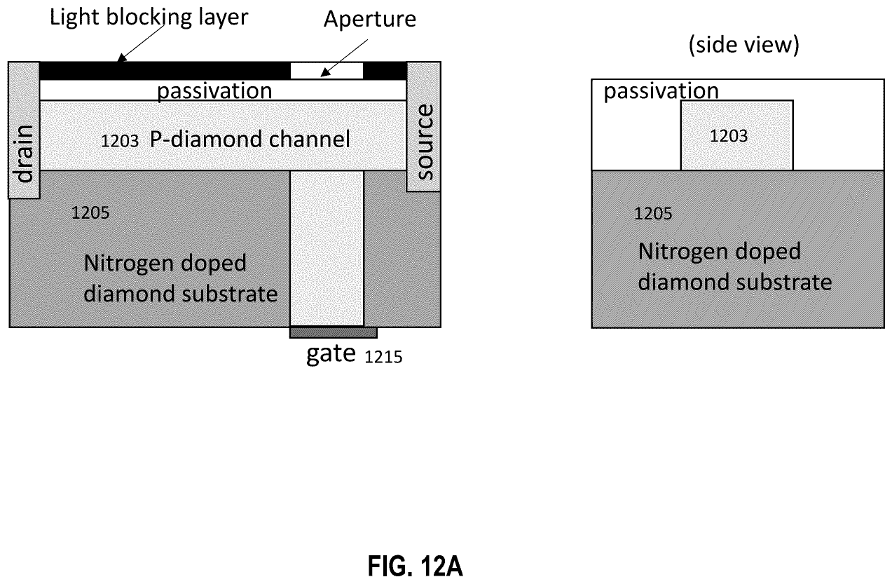

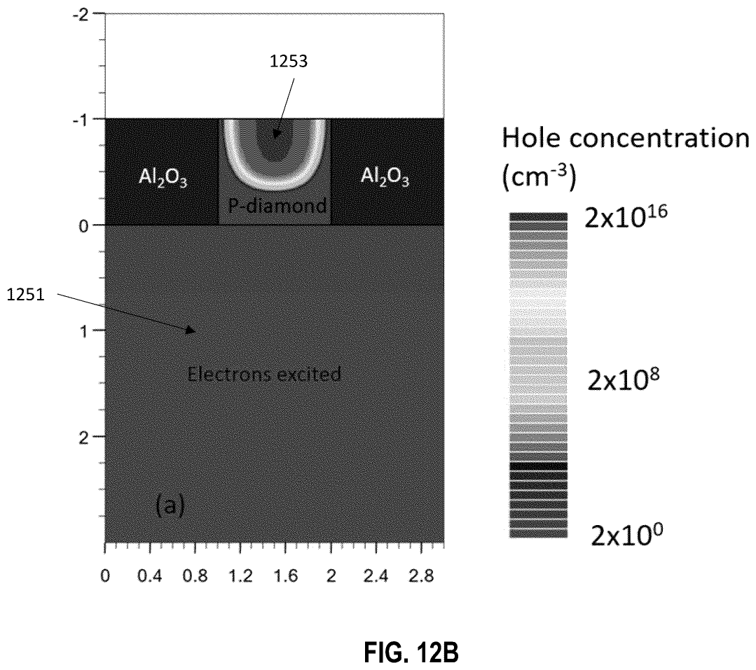

FIG. 12A illustrates an example planar JFET switch corresponding to the configuration shown in FIG. 2 in accordance with one or more embodiments of the present technology. A planar configuration, as shown in the side view on the right, is a configuration in which the P-diamond layer 1203 is deposited on top of the N-type substrate 1205. Fabrication of a planar JFET starts with a diamond substrate with nitrogen doping of 10¹⁷-10¹⁹ cm⁻³ range. A P-type boron-doped diamond layer of 0.5-1 um is epitaxially deposited, followed by deposition of a thin (e.g., tens of nanometers, [1 nm, 100 nm]) heavily boron doped diamond P+ layer for contacts. Finally, a dielectric layer is deposited on top for passivation. The channel region is defined by etching of the Player. The source and drain contacts are formed by etching through the passivation layer, the P+ layer, followed by metal deposition. Gate contact is formed by metal deposition to the backside of the diamond substrate. An optical aperture is formed by etching of light-absorbing mask on top of device. The fabrication of the planar JFET configurations can be accomplished easily.

FIG. 12B illustrates an example distribution of hole concentration profile of a planar configuration at time of 300 ns after the gate light is turned on in accordance with one or more embodiments of the present technology. As shown in FIG. 12B, free electrons that are excited in the diamond substrate and the lower portion of the P-diamond layer can be modulated by gate voltage. The optical gate function is activated by an external or internally integrated light source. With gate light, electrons 1251 are photo-excited from deep nitrogen sites to the conduction band, and the hole channel 1253 width is modulated by varying the gate voltage. The switching speed of a planar device is dependent on factors such as the gate light intensity, light absorption coefficient, P-type doping concentration, and P-layer thickness etc. For example, in a planar FET, the required light intensity can be in the range of 1 kW/cm² to achieve turn-on and turn-off time in the range of less than 100 nano seconds. The switching speed is determined by how fast the gate voltage 1215 is transferred to the channel region.

As discussed in connection with FIG. 7, the hole channel in the P-layer needs to be depleted to switch the device to its OFF state. To enable faster switching speed and lower gate light intensity, the P-diamond layer can be at least partially embedded inside the diamond substrate. In some embodiments, the hole channel is modulated in three directions or four directions to enable much faster turn-on and turn-off transients, thereby greatly reducing the required gate light intensity.

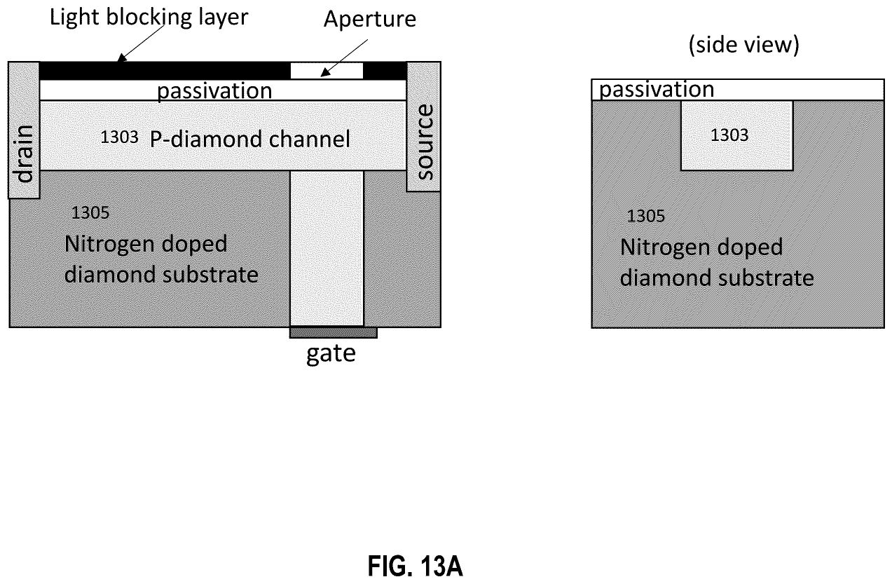

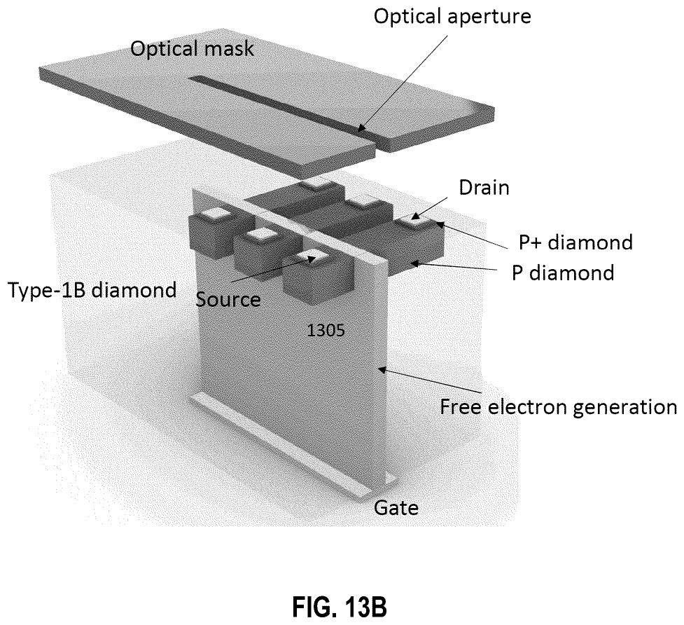

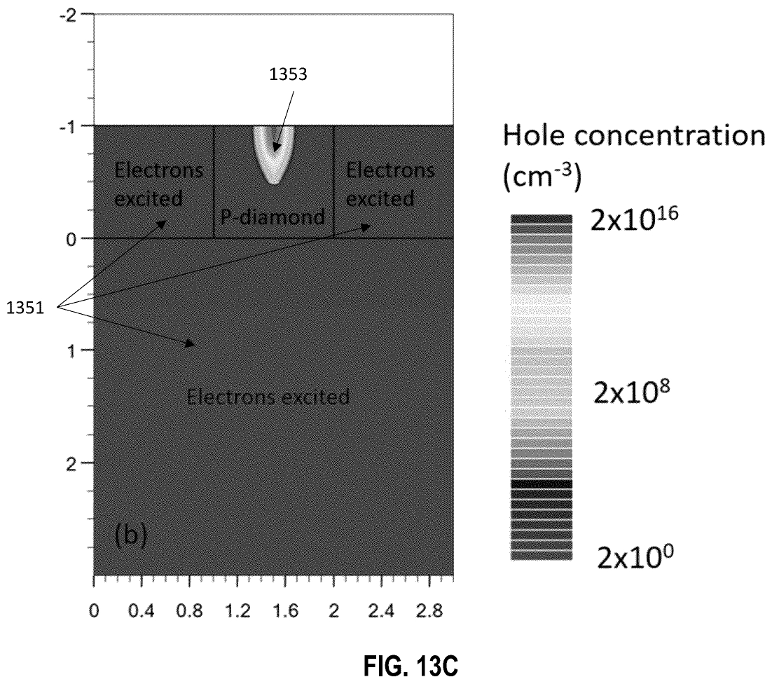

FIG. 13A illustrates an example partially embedded P-layer JFET switch in accordance with one or more embodiments of the present technology. As shown in the side view on the right, in this example, the P-diamond layer 1303 is at least partially embedded in the N-type substrate 1305, with three sides on contact with the N-type substrate and the top surface in contact with the passivation layer. This type of configurations is also referred to as Fin-FET configurations. Fabrication of a partially embedded p-layer JFET starts with the same diamond substrate. FIG. 13B illustrates an example three-dimensional schematic diagram of multiple Fin-FET devices in parallel in accordance with one or more embodiments of the present technology. The P-channel region is provided by lithography and etching into the substrate 1305, followed by a thin film of boron doped diamond deposition to fill the trenches, then etch-back and planarization (e.g., by dry etching). A heavily boron doped P+ diamond layer is deposited as contact layer followed by a passivation layer. The source, drain, gate contacts and optical aperture are formed in a similar way as planar JFET shown in FIG. 12A.

With this design, the optical gate surrounds the P-type conduction channel when the gate light is turned on. FIG. 13C illustrates an example distribution of hole concentration profile of a Fin-FET configuration at time of 300 ns after the gate light is turned on in accordance with one or more embodiments of the present technology. As shown in FIG. 13C, with gate light, electrons 1351 are photo-excited from deep nitrogen sites to the conduction band. Due to the three-sided contact with the N-type substrate, more holes are depleted in the P-diamond layer as compared to the planar configuration, resulting in a smaller hole channel (e.g., the number of charge carriers) 1353 being present.

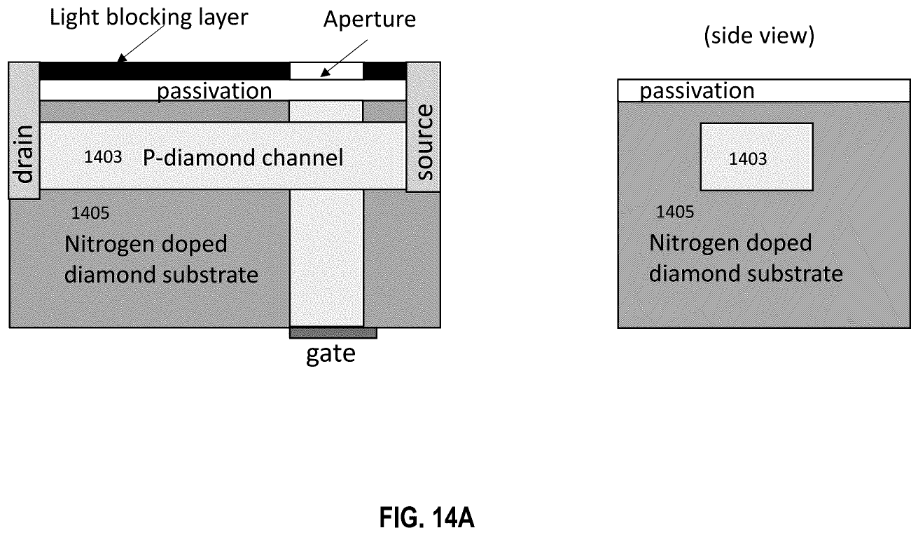

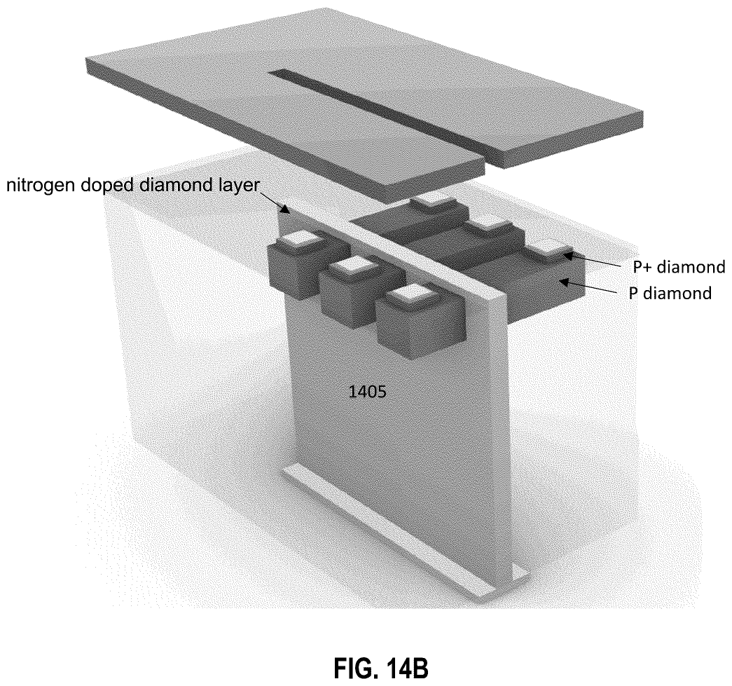

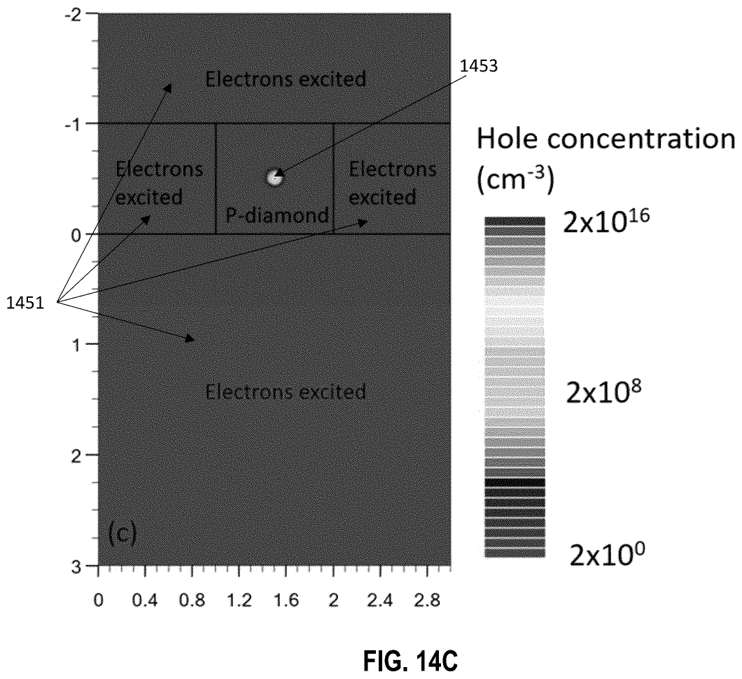

FIG. 14A illustrates an example fully embedded P-layer JFET switch in accordance with one or more embodiments of the present technology. As shown in the side view on the right, in this example, the P-diamond layer 1403 is fully embedded in the N-type substrate 1405, with all sides of the p-diamond layer 1403 being in contact of the N-type substrate 1405. This type of configurations can also be referred to as Optical-Gate-All-Around (OGAA) configurations. FIG. 14B illustrates an example three-dimensional schematic diagram of multiple OGAA-FET devices connected in parallel in accordance with one or more embodiments of the present technology. Fabrication of an OGAA-FET starts with the same diamond substrate. The P-channel region is provided by lithography and etching into the substrate, followed by a thin film of boron doped diamond deposition. After the P channel layer is planarized, a nitrogen doped diamond layer (e.g., ˜1 um) is deposited on top, followed by etching to expose the source and drain contact regions. Then p+ diamond contact and passivation layers are deposited, etched, then metal deposited to form source and drain contacts. Gate contact is formed by metal deposition on the backside of the substrate. Optical aperture is formed by etching through the light absorbing mask.

With this design, the optical gate is all around the P-type conduction channel when the gate light is turned on. FIG. 14C illustrates an example distribution of hole concentration profile of an OGAA-FET configuration at time of 300 ns after the gate light is turned on in accordance with one or more embodiments of the present technology. As shown in FIG. 14C, with gate light, electrons 1451 are photo-excited from deep nitrogen sites to the conduction band. The hole channel 1453 (e.g., the charge carriers) has a very small size and is almost fully depleted, so the channel is turned off very quickly. The channel resistances can be calculated and normalized to that of the planar FET. The calculated ratios are 1:100:6420 (planar:partial:full), which suggests the channel currents are 100 times lower in the partially embedded FET and 6420 times lower in fully embedded FET at time of 300 ns.

Technology Computer Aided Design (TCAD) transient simulations were conducted to compare the differences in switching speeds. In the simulations, following device parameters were used: (1) diamond substrate thickness: 300 μm, (2) nitrogen concentration: 1×10¹⁷ cm⁻³, (3) P-layer thickness: 1 μm, (4) P-layer doping concentration: 2×10¹⁶ cm⁻³, (5) P-channel width: 1 μm, (6) gate voltage: 15 V, (7) drain voltage: low (<10 V), (8) gate light absorption coefficient: 100 cm⁻¹, and (9) gate light intensity: 10 W/cm².

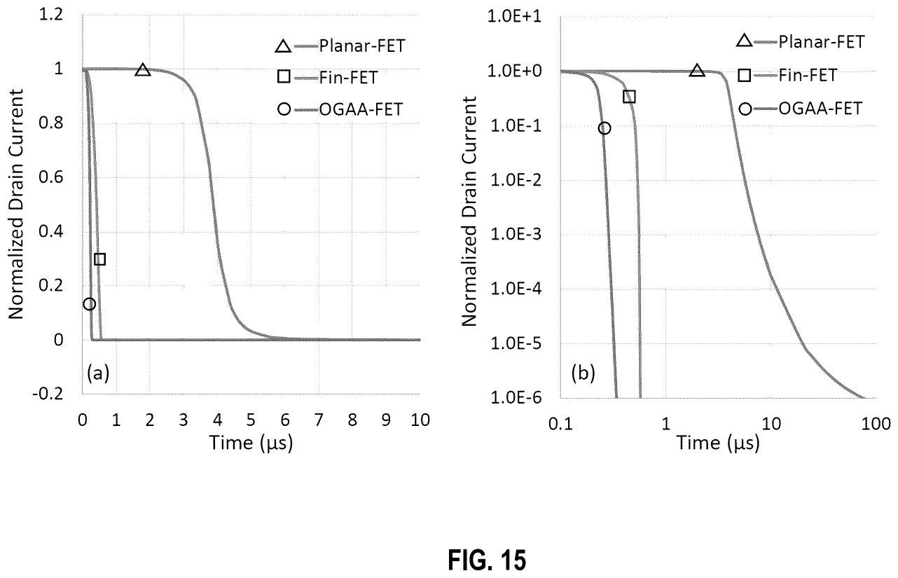

During the simulations, drain voltage and gate voltage were first ramped up to the set values specified above. Then the gate light was turned on at time of t₀=0. The drain current was monitored over time. FIG. 15 illustrates example plots showing transient drain currents normalized to their maximum values in linear scale (left) and logarithm scale (right) in accordance with one or more embodiments of the present technology. Using the example parameters, it took 4.5 us for drain current to drop down to its 10% in the planar FET, and 0.5 us, 0.25 us for the Fin-FET and the OGAA-FET respectively. If the desired On/Off current ratio is set to 10⁶, the turn off time are 80 us, 0.57 us and 0.33 us for planar, Fin-FET and OGAA-FETs, respectively. Using the Fin-FET and OGAA-FET configurations, a much lower gate light intensity can be used (e.g., ˜5 to 15 W/cm² versus 1 kW/cm² in planar configurations to achieve turn-on and turn-off time in the range of less than 100 nano seconds).

With high-voltage applications, high local electric fields can be observed in the vicinity of corners between the optical gate and P channel. If the electric fields are too high, they may break down the device. Field management is used to reduce the field and obtain a higher blocking voltage. The conventional method of field management includes use of a field plate or junction termination extension. A field plate design is complicated in an optical gated device. The JTE is typically a zone with gradually changed resistance or a set of conductive zones separated by resistive zones. They are typically formed by ion implantation. However, due to diamond's unique structure and extreme material strength, the implantation depth is limited to tens of nanometers. Combined with lack of shallow dopants, traditional JTE is less effective in diamond transistors.

Field management for diamond JTE can be achieved by utilizing a properly designed JTE mask and a JTE laser without ion implantation process. Referring back to FIG. 11, in some embodiments, in addition to the light blocking layer 1121, the zone with gradually changed resistance is realized by optimized laser intensity profile. A mask 1123 (e.g., gradually light absorbing material having a gradient index or a gradient thickness) is deposited on top of passivation layer above the channel region.

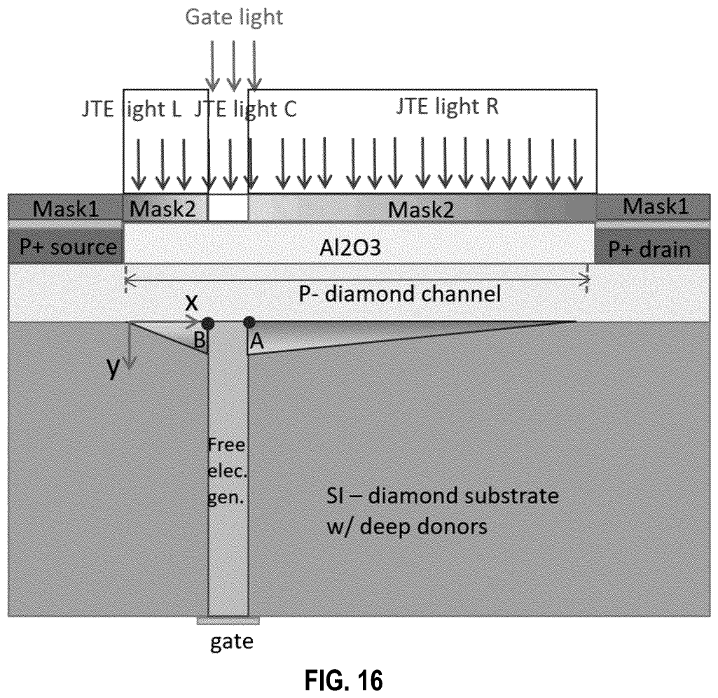

FIG. 16 illustrates yet another example diamond JFET in accordance with one or more embodiments of the present technology. In this example configurations, the opaque blocking layer/mask (Mask1) is deposited on top of the passivation layer. A second, gradient mask (Mask2) is positioned on both sides of the gate light on the passivation layer. In some embodiments, part of Mask2 is etched open to allow the maximum transmission of gate light. The etched window position can define the gate light dimension. In some embodiments, the etched window can be positioned at the center of Mask2.

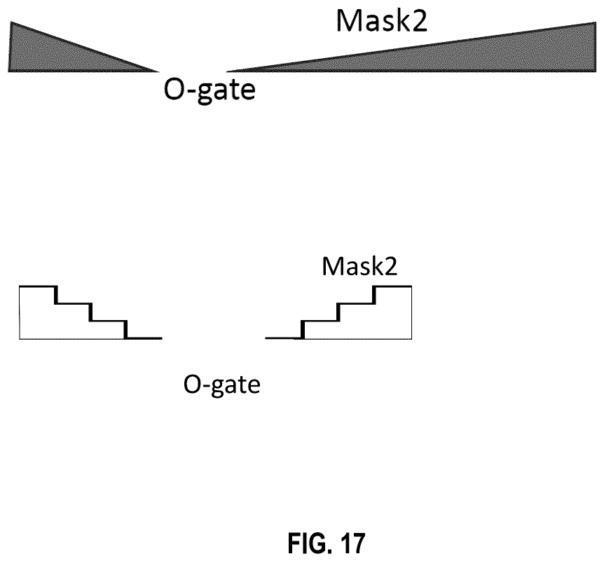

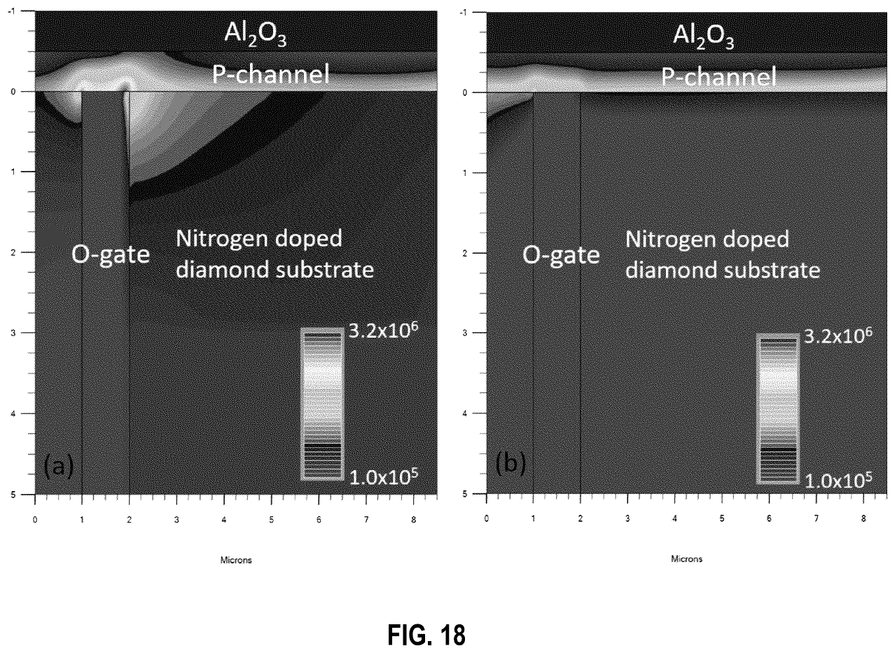

Mask2 is used to modify the JTE light intensity at the interface of P channel and N-type substrate. It can be done by either monotonically increasing the mask layer thickness from optical gate position towards source or drain, or varying the mask material composition or both, to ensure the JTE light intensity gradually decreases from point A to drain, and point B to source. FIG. 17 illustrates two example implementations of a gradient mask (Mask2) in accordance with one or more embodiments of the present technology. In some embodiments, as shown in the upper part of FIG. 17, Mask2 has a gradually increasing thickness from optical gate position towards source or drain. In some embodiments, as shown in the lower part of FIG. 17, the mask layer has a fine step-shaped geometry to achieve the gradual change of light absorption. Such a JTE laser profile creates a region around the optical gate with gradually changed resistance serving as an optical JTE. The absorption depth of gate light is in the order of substrate thickness to ensure efficient transfer of gate voltage.

The JTE laser is designed to be absorbed close to the interface. A uniform absorption of high intensity JTE light across the entire substrate potentially results in gate voltage transferring to a location close to the drain and leads to an early break-down. The required JTE light intensity is high enough at the interface to make it functional and low enough at the bottom of the substrate to stop the gate voltage transfer through JTE light region. For example, the JTE light intensity can be in the range of 0.01-100 W/cm². In some embodiments, a shorter wavelength JTE laser can be used. For example, an example range of wavelength is 230 nm-532 nm. In some circumstances, one laser source can be used for both gate light and JTE light.

Analogous to the channel memory effect of DOG-FET discussed in connection with FIGS. 5A-6F, the space charge region formed by JTE light is locked when the light is turned off. Therefore, a reduced electric field profile with a long period of time is maintained. The retention time is in the range of hours to days, depending on the substrate and epilayer quality.

FIG. 18 illustrates an example comparison of electric field profiles with and without JTE light in a DOG-FET under the steady state in accordance with one or more embodiments of the present technology. In this example, the diamond substrate is 300 μm thick with 2×10¹⁸ cm⁻³ doped nitrogen. The P-type epilayer is 0.5 μm thick with 1×10¹⁷ cm⁻³ doped boron. The gate light intensity is 1 kW/cm², and absorption coefficient is 40 cm⁻¹. The source, drain, and gate voltages are set to 0, −1000, and 100V, respectively.

The JTE light profile is tuned by Mask2 to have an exponentially decreased intensity that is described by I_{x,y}=Iₚₑₐₖe^{-αx(x-x}^{₀}⁾e^{-αy(y-y}^{₀}⁾, where Iₚₑₐₖ is the peak power of 1 W/cm², x₀ and y₀ are coordinates of point A or B, αₓ is the lateral attenuation of 500 cm⁻¹, and α_{y} is the absorption coefficient of JTE light of 500 cm⁻¹. Without JTE light, maximum electric fields appear at point A and point B, as shown in the left of FIG. 18. Turning on JTE light greatly reduces the electric field magnitude at those spots, as shown in the right of FIG. 18.

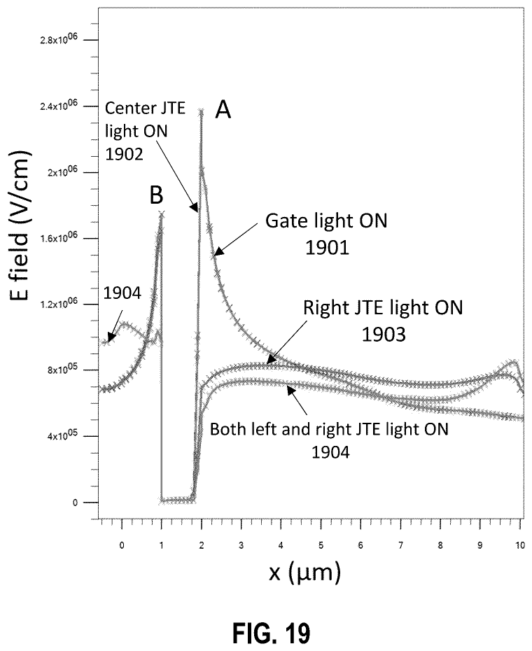

In order to demonstrate the effectiveness of JTE light, a TCAD simulation was conducted by turning on JTE light at different regions sequentially. FIG. 19 illustrates example simulated electric fields at the interface of P channel and substrate in accordance with one or more embodiments of the present technology. First, turn on the gate light. The resulting electric field is shown as the x curve (1901). The local field peaks are observed around the optical gate (point A and B). After that, turn on the center JTE light, which aligns with the optical gate light. The resulting curve of center JTE light (1902) aligns exactly with the optical gate light curve (1901). The electric field exactly overlays with gate light only condition which suggests no JTE effect.

The right JTE light is then turned on. The resulting curve is shown as 1903. The local field peak at point A is reduced from 2.4×10⁶ to 8×10⁵ V/cm. The local high field at point B remains about the same. Finally, the left JTE light on the left is also turned on, resulting in curve 1904 with both right and left JTE light being on. The high field at point B is reduced from 1.8×10⁶ to 1.0×10⁶ V/cm. To reach a higher switching speed, Fin-FET and/or OGAA FTE structures as shown in FIG. 13A and FIG. 14A can be adopted. When the P channel is buried inside nitrogen doped diamond layer and/or substrate, the three-dimensional confined channel allows for a higher switching speed with a lower required gate light intensity.

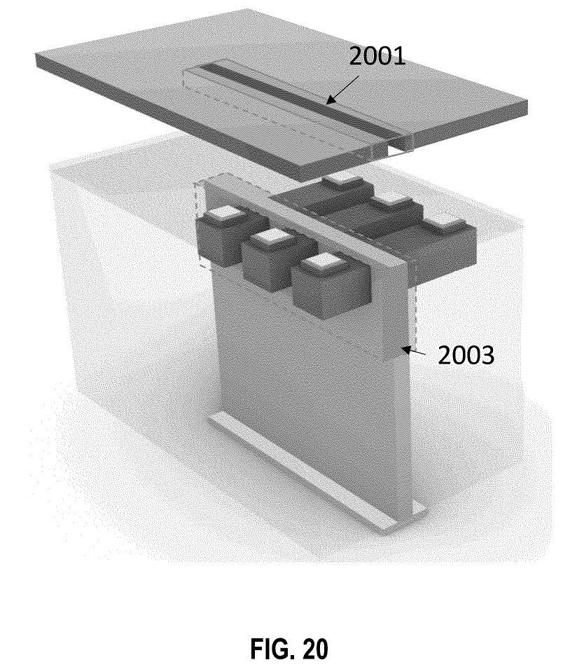

FIG. 20 illustrates an example three-dimensional schematic diagram of an optical JTE in OGAA DOG-FET in accordance with one or more embodiments of the present technology. The integrated gate and JTE light mask (2001) is filled with gradually light absorbing material, allowing JTE light absorption around the optical gate (2003) and close to the P channel interface.

The gate light aperture is etched open inside the JTE mask allowing for maximum gate light intensity. Such a design ensures high field regions in DOG-FET are fully enclosed by JTE light. The high field regions in a set of parallel arranged DOG-FETs are fully covered by JTE light, and peak electric fields are effectively suppressed. The set of parallel arranged DOG-FETs can then be separated to provide multiple DOG-FET devices.

Some preferred embodiments according to the disclosed technology adopt the following solutions.

1. A switch operable under high-voltage and high-power, comprising: an N-type diamond region doped with a donor material; a P-type diamond layer doped with an acceptor material and at least partially positioned within the N-type diamond region; one or more apertures configured to allow illumination from a light source to reach an internal region of the switch; a source contact and a drain contact that are at least partially in contact with the P-type diamond layer; and a gate in contact with at least an area of the N-type diamond region, wherein the N-type diamond region, upon receiving the illumination and application of a first bias voltage, is configured to generate a conduction current that remains on in an absence of the illumination.

2. The switch of solution 1, wherein the P-type diamond layer is positioned in one or more trenches in the N-type diamond region such that a bottom surface and at least part of side surfaces of the P-type diamond layer are in contact with the N-type diamond region.

3. The switch of solution 2, wherein each of the side surfaces in its entirety is in contact with the N-type diamond region.

4. The switch of solution 1, wherein the P-type diamond layer is positioned in one or more trenches in the N-type diamond region such that all surfaces of the P-type diamond layer are in contact with N-type diamond.

5. The switch of solution 1, wherein the donor material comprises nitrogen, and wherein the acceptor material comprises boron.

6. The switch of solution 1, further comprising: a passivation layer in contact with the N-type diamond region and the gate.

7. The switch of solution 1, further comprising: a passivation layer; and a contact layer between the passivation layer and the N-type diamond region, the contact layer comprising a doped P+ diamond layer.

8. The switch of solution 1, wherein a thickness of the P-type diamond layer is between 0.1 um to 10 μm.

9. The switch of solution 1, configured to switch between an ON state having the conduction current and an OFF state within 1 us upon an intensity of the illumination from the light source is in a range of 5 to 15 W/cm².

10. The switch of solution 1, comprising: one or more gradient masks surrounding the one or more apertures and a light blocking material.

11. The switch of solution 10, wherein the one or more gradient masks comprise at least one of: a gradually increasing thickness from the one or more apertures towards the source contact or the drain contact, or a material having a gradually changing absorption coefficient.

12. The switch of solution 1, wherein the donor material comprises nitrogen, and wherein the N-type diamond region is doped at a doping level between 10¹⁸ to 10¹⁹ cm⁻³.

13. The switch of solution 1, wherein a photon energy of the illumination is greater than an activation energy of the donor material.

14. The switch of solution 1, wherein a wavelength of the illumination is smaller than a threshold value that is determined based on characteristics of the donor material.

15. The switch of solution 1, further comprising: the light source that is configured to emit the illumination at a particular wavelength.

16. The switch of solution 1, further comprising: a second light source configured to provide additional illumination to excite free holes in the P-type diamond layer, wherein the additional illumination has a greater energy than an activation energy of the acceptor material and a smaller energy than an activation energy of the donor material.

17. A switch operable under high-voltage and high-power, comprising: a P-type diamond layer doped with an acceptor material; an N-type diamond region doped with a donor material, wherein the P-type diamond layer is at least partially in contact with the N-type diamond region; a layer comprising an aperture configured to allow illumination from a light source to pass through to reach the N-type diamond region; and one or more gradient masks at least partially surrounding the aperture from multiple sides to allow variable absorption or transmission of illumination from the light source to reach an internal region of the switch, wherein the N-type diamond region, upon receiving the illumination and application of a first bias voltage, is configured to generate a conduction current that remains on in an absence of the illumination.

18. The switch of solution 17, wherein at least one of the one or more gradient masks has a geometrical structure with a variable thickness that monotonically increases away from the aperture.

19. The switch of solution 17, wherein at least one of the one or more gradient masks comprises a step-shaped geometry to obtain a gradual increase of light absorption away from the aperture.

20. The switch of solution 17, wherein at least one of the one or more gradient masks comprises a material having a gradually changing absorption coefficient to obtain a gradual increase of light absorption away from the aperture.

21. The switch of solution 17, wherein gradient masks are positioned to fully surround the aperture such that a gradually reduced electron concentration is formed around where the illumination interfaces the N-type diamond region and the P-type diamond layer.

22. The switch of solution 17, wherein the donor material comprises nitrogen, and wherein the acceptor material comprises boron.

23. The switch of solution 17, wherein a thickness of the P-type diamond layer is between 0.1 um to 10 um.

24. The switch of solution 17, further comprising: a passivation layer; and a contact layer between the passivation layer and the N-type diamond region, the contact layer comprising a doped P+ diamond layer.

25. The switch of solution 17, configured to switch between an ON state having the conduction current and an OFF state within 1 us upon an intensity of the illumination from the light source is in a range of 5 to 15 W/cm².

26. The switch of solution 17, wherein the one or more gradient masks are positioned to partially surround the aperture such that a gradually reduced electron concentration is formed along one side of where the illumination interfaces the N-type diamond region and the P-type diamond layer.

27. The switch of solution 17, wherein a bottom surface of the P-type diamond layer is in contact with the N-type diamond region.

28. The switch of solution 17, wherein the donor material comprises nitrogen, and wherein the N-type diamond region is doped at a doping level between 10¹⁸ to 10¹⁹ cm⁻³.

29. The switch of solution 17, wherein a photon energy of the illumination is greater than an activation energy of the donor material.

30. The switch of solution 17, wherein a wavelength of the illumination is smaller than a threshold value that is determined based on characteristics of the donor material.

31. The switch of solution 17, further comprising: the light source that is configured to emit the illumination at a particular wavelength.

32. The switch of solution 17, further comprising: a second light source configured to provide additional illumination to excite free holes in the P-type diamond layer, wherein the additional illumination has a greater energy than an activation energy of the acceptor material and a smaller energy than an activation energy of the donor material.

While this patent document contains many specifics, these should not be construed as limitations on the scope of any invention or of what may be claimed, but rather as descriptions of features that may be specific to particular embodiments of particular inventions. Certain features that are described in this patent document in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Moreover, the separation of various system components in the embodiments described in this patent document should not be understood as requiring such separation in all embodiments.

Only a few implementations and examples are described, and other implementations, enhancements and variations can be made based on what is described and illustrated in this patent document.

What is claimed is:

1. A switch operable under high-voltage and high-power, comprising:
an N-type diamond region doped with a donor material;
a P-type diamond layer doped with an acceptor material and at least partially positioned within the N-type diamond region;
one or more apertures configured to allow illumination from a light source to reach an internal region of the switch;
a source contact and a drain contact that are at least partially in contact with the P-type diamond layer; and
a gate in contact with at least an area of the N-type diamond region, wherein the N-type diamond region, upon receiving the illumination and application of a first bias voltage, is configured to generate a conduction current that remains on in an absence of the illumination.

2. The switch of claim 1, wherein the P-type diamond layer is positioned in one or more trenches in the N-type diamond region such that a bottom surface and at least part of side surfaces of the P-type diamond layer are in contact with the N-type diamond region.

3. The switch of claim 2, wherein each of the side surfaces in its entirety is in contact with the N-type diamond region.

4. The switch of claim 1, wherein the P-type diamond layer is positioned in one or more trenches in the N-type diamond region such that all surfaces of the P-type diamond layer are in contact with N-type diamond.

5. The switch of claim 1, wherein the donor material comprises nitrogen, and wherein the acceptor material comprises boron.

6. The switch of claim 1, further comprising:
a passivation layer in contact with the N-type diamond region and the gate.

7. The switch of claim 1, further comprising:
a passivation layer; and
a contact layer between the passivation layer and the N-type diamond region, the contact layer comprising a doped P+ diamond layer.

8. The switch of claim 1, wherein a thickness of the P-type diamond layer is between 0.1 um to 10 μm.

9. The switch of claim 1, configured to switch between an ON state having the conduction current and an OFF state within 1 us upon an intensity of the illumination from the light source is in a range of 5 to 15 W/cm².

10. The switch of claim 1, comprising:
one or more gradient masks surrounding the one or more apertures and a light blocking material.

11. The switch of claim 10, wherein the one or more gradient masks comprise at least one of:
a gradually increasing thickness from the one or more apertures towards the source contact or the drain contact, or
a material having a gradually changing absorption coefficient.

12. A switch operable under high-voltage and high-power, comprising:
a P-type diamond layer doped with an acceptor material;
an N-type diamond region doped with a donor material, wherein the P-type diamond layer is at least partially in contact with the N-type diamond region;
a layer comprising an aperture configured to allow illumination from a light source to pass through to reach the N-type diamond region; and
one or more gradient masks at least partially surrounding the aperture from multiple sides to allow variable absorption or transmission of illumination from the light source to reach an internal region of the switch;
wherein the N-type diamond region, upon receiving the illumination and application of a first bias voltage, is configured to generate a conduction current that remains on in an absence of the illumination.

13. The switch of claim 12, wherein at least one of the one or more gradient masks has a geometrical structure with a variable thickness that monotonically increases away from the aperture.

14. The switch of claim 12, wherein at least one of the one or more gradient masks comprises a step-shaped geometry to obtain a gradual increase of light absorption away from the aperture.

15. The switch of claim 12, wherein at least one of the one or more gradient masks comprises a material having a gradually changing absorption coefficient to obtain a gradual increase of light absorption away from the aperture.

16. The switch of claim 12, wherein gradient masks are positioned to fully surround the aperture such that a gradually reduced electron concentration is formed around where the illumination interfaces the N-type diamond region and the P-type diamond layer.

17. The switch of claim 12, wherein the donor material comprises nitrogen, and wherein the acceptor material comprises boron.

18. The switch of claim 12, wherein a thickness of the P-type diamond layer is between 0.1 um to 10 um.

19. The switch of claim 12, further comprising:
a passivation layer; and
a contact layer between the passivation layer and the N-type diamond region, the contact layer comprising a doped P+ diamond layer.

20. The switch of claim 12, configured to switch between an ON state having the conduction current and an OFF state within 1 us upon an intensity of the illumination from the light source is in a range of 5 to 15 W/cm².

21. The switch of claim 12, wherein the one or more gradient masks are positioned to partially surround the aperture such that a gradually reduced electron concentration is formed along one side of where the illumination interfaces the N-type diamond region and the P-type diamond layer.

22. The switch of claim 12, wherein a bottom surface of the P-type diamond layer is in contact with the N-type diamond region.
